(19) United States
(12) Patent Application Publication
(10) Pub. No.: US 2017/0309321 A1
(43) Pub. Date: Oct. 26, 2017

(54) Peak Current Bypass Protection Control Device Applicable in MRAM

(71) Applicant: Lyontek Inc., Hsinchu City (TW)

(72) Inventors: LING-YUEH CHANG, Hsinchu City (TW); PENG-JU HUANG, Miaoli County (TW); CHI-CHENG HUNG, Hsinchu City (TW)

(21) Appl. No.: 15/239,013

(22) Filed: Aug. 17, 2016

(30) Foreign Application Priority Data
Apr. 26, 2016 (TW) 105113000

(51) Int. Cl. G11C 11/16

(52) U.S. Cl. CPC G11C 11/1695; G11C 11/1675; G11C 11/1657; G11C 11/1673

(57) ABSTRACT

A peak current bypass protection control device applicable in MRAM is provided. In a memory unit array formed of a plurality of magnetic memory bit cells, each column of magnetic memory bit cells is connected in parallel with a bypass unit. When the magnetic memory bit cells of the memory unit array are being read/written, at the moment of switching on a switch, the bypass unit connected in parallel to the magnetic memory bit cells allows an instantaneous peak current to be guided out and prevents it from flowing through the magnetic memory bit cells.

### CROSS-REFERENCE TO RELATED APPLICATIONS

This application claims the priority of Republic of China Patent Application No. 105113000 filed on Apr. 26, 2016, in the State Intellectual Property Office of the R.O.C., the disclosure of which is incorporated herein by reference.

### BACKGROUND OF THE INVENTION

### Field of the Invention

The invention relates to data access technologies, and more particularly, to a peak current bypass protection control device applicable in MRAM.

### Descriptions of the Related Art

Magnetic Random Access Memory (MRAM) is a non-volatile memory and is made of a different material from current Dynamic Random Access Memory (DRAM) or Static Random Access Memory (SRAM), such that when an electronic product loses power or is shut down, MRAM data is still keep. MRAM has several advantages such as low power consumption, non-volatility and fast read/write capability. A basic core memory bit cell of the MRAM is composed of a magnetic tunnel junction (MTJ) element and a switch transistor, and the MTJ element acts as a variable resistance. As shown in FIGS. 1a and 1b, the MTJ element has three layers, including: an upper free layer 10, a middle tunnel insulator layer 11, and a lower fixed layer 12, wherein the magnetic polarization orientation in the free layer 10 is changeable, while the magnetic polarization orientation in the fixed layer 12 is constant. When the magnetic orientations in the free layer 10 and the fixed layer 12 are the same (see FIG. 1a), the MTJ element is resistance low (RL). When the magnetic orientations in the free layer 10 and the fixed layer 12 are opposite, the MTJ element is resistance high (RH). Digital data (0 or 1) can be stored in the MTJ element by writing different polarity currents to magnetize orientations of magnetic layers in the MTJ element. For reading, as different magnetic orientations allow the MTJ element to have different resistance characteristics (that is, RL or RH as described above), the digital data can be differentiated. Moreover, when the MTJ element is of different resistance characteristics (RL and RH), the write and read operations have respective working voltage ranges thereof, as shown in FIG. 1c.

FIG. 2 shows a MRAM circuit architecture. The MRAM circuit architecture comprises a memory bit cell array 20 (take N rows, X1 columns as an example), a control circuit 21 for performing a write operation on the memory bit cell array 20, and a control circuit 22 for performing a read operation on the memory bit cell array 20. The memory bit cell array 20 is made up of N rows of magnetic memory bit cells 200, wherein each magnetic memory bit cell 200 comprises a MTJ element MTJ0 and a drain of a transistor 2001 connected in series to a terminal of the MTJ element MTJ0. The above circuits further comprise: N word lines WL1 to WLn, which are respectively connected to gates of the above transistors of the magnetic memory bit cells and are for controlling on/off actions of the transistors; a bit line BL connected to another terminal of each MTJ element; and a source line SL connected to a source of each MTJ element. As shown in FIG. 2, the control circuits 21, 22 are respectively connected to the memory bit cell array 20 via switches CS. When the write operation is performed on the MRAM, amplitude of a write current should be maintained within a certain range, which must be sufficient to change the resistance state of each MTJ element but not exceed the breakdown voltage thereof. When the read operation is performed on the MRAM, amplitude of a read current should be maintained below a certain amplitude to avoid any read disturb failures because too large amplitude causes type change of the data stored in the MTJ elements. Referring to FIG. 3, it shows a control current WL, CS for performing the write operation on the MRAM, a control current Din for performing the read operation on the MRAM, and a current flowing through the MTJ element. As shown in FIG. 3, at the moment of applying the write control current WL, CS or the read control current Din to turn on a control switch of the circuit, an instantaneous peak current is generated on the MTJ element MTJ0 (as indicated by the dotted areas in FIG. 3). The instantaneous peak current has a current path WP0 for writing signal “0” (as shown in FIG. 4) or a current path WP1 for writing signal “1” (as shown in FIG. 5) through the MTJ element MTJ0. In a severe situation with a write control voltage being larger than the breakdown voltage of the MTJ element MTJ0 (the V-R graph for the MTJ element as shown in FIG. 1c), even though the MTJ element MTJ0 might not be immediately damaged, the reliability of the MTJ element MTJ0 would be reduced as time goes by. Further, when reading, the instantaneous peak current has a read path RP through the MTJ element MTJ0 as shown in FIG. 6. In this case, even if data read mistake might not be caused, the reliability of the MTJ element MTJ0 would be undesirably reduced.

Therefore, how to make a new MRAM circuit architecture in order to solve the above problems of the conventional MRAM circuit is an important topic in the art.

### SUMMARY OF THE INVENTION

In view of the above drawbacks of the prior art, a primary object of the invention is to provide a peak current bypass protection control device applicable in Magnetic Random Access Memory (MRAM), which allows a peak current generated at the moment of switching on a selection switch to be guided out and prevents the peak current from flowing through magnetic memory bit cells on a read/write path, so as to keep currents on MTJ elements within appropriate working ranges thereof and thus assure reliability of the MTJ elements.

To achieve the above and other objects, a peak current bypass protection control device applicable in MRAM is provided in the invention, wherein the MRAM is controlled by a source line control circuit, an address switching circuit unit, a bit line control circuit and a read current control circuit to allow read/write operations to be performed thereon. The MRAM comprises: a memory bit cell array including a plurality of rows of magnetic memory bit cells and a plurality of columns of magnetic memory bit cells, wherein each of the magnetic memory bit cells includes a bit line control terminal, a word line control terminal and a source line control terminal. The peak current bypass protection control device of the invention comprises: a bit line connected to the bit line control circuit and provided for each of the columns of magnetic memory bit cells, wherein the bit line is connected to the bit line control terminal of each of the magnetic memory bit cells in a corresponding one of the columns; a word line connected to the address switching circuit unit and provided for each of the rows of magnetic memory bit cells, wherein the word line is connected to the word line control terminal of each of the magnetic memory bit cells in a corresponding one of the rows; and a bypass unit provided for each of the columns of magnetic memory bit cells, wherein the bypass unit is connected to the bit line control terminals and the source line control terminals of the magnetic memory bit cells in a corresponding one of the columns.

In the peak current bypass protection control device of the invention, the magnetic memory bit cell includes a MTJ element and a switch unit connected to a terminal of the MTJ element. Preferably, the switch unit is a transistor having a drain connected to the terminal of the MTJ element, wherein another terminal of the MTJ element serves as the bit line control terminal, a gate of the transistor serves as the word line control terminal, and a source of the transistor serves as the source line control terminal.

In the peak current bypass protection control device of the invention, the bypass unit is a switch unit. The switch unit is a bypass transistor turned on at a low potential or a high potential

In the peak current bypass protection control device of the invention, a gate of the bypass transistor is connected to the address switching circuit unit, and the bit line control terminals and the source line control terminals of the magnetic memory bit cells in each of the columns are respectively connected to a column selection switch, wherein the column selection switch is connected to the address switching circuit unit. The address switching circuit unit is for outputting a column selection control signal to the column selection switch, for outputting a row selection control signal to one of the rows of magnetic memory bit cells, and for outputting a bypass signal to the gate of the bypass transistor. Moreover, the column selection switch is a selection transistor having a gate connected to the address switching circuit unit, for turning on one of the columns of magnetic memory bit cells according to the column selection control signal.

Therefore, in the peak current bypass protection control device of the invention, a bypass unit is provided and connected in parallel to each column of magnetic memory bit cells in a memory bit cell array of a conventional MRAM circuit. This allows an instantaneous current generated at the moment of switching on a selection switch to be guided out from MTJ elements within the magnetic memory bit cells to a ground terminal during read/write operations. Thereby, reliability of the MTJ elements is improved and correctness of digital data being read/written is assured.

### BRIEF DESCRIPTION OF THE DRAWINGS

The above and other aspects, features and other advantages of the present invention will be more clearly understood from the following detailed description taken in conjunction with the accompanying drawings, in which:

FIG. 1a is a schematic diagram showing a conventional MTJ element being resistance low (RL); FIG. 1b is a schematic diagram showing the MTJ element being resistance high (RH); and FIG. 1c is a graph of write and read operation voltages when the MTJ element is of different resistance characteristics.

FIG. 2 is a schematic diagram showing a conventional MRAM circuit architecture.

FIG. 3 is a schematic diagram showing control signals and MTJ element circuit signals which are used when performing read and write operations on the MRAM shown in FIG. 2.

FIG. 4 is a schematic diagram showing a current path for writing signal “0” in the conventional MRAM circuit architecture.

FIG. 5 is a schematic diagram showing a current path for writing signal “1” in the conventional MRAM circuit architecture.

FIG. 6 is a schematic diagram showing a current path for performing the read operation in the conventional MRAM circuit architecture.

FIG. 7 is a circuit architecture schematic diagram of a peak current bypass protection control device applicable in MRAM of the invention.

FIG. 8 is another circuit architecture schematic diagram of the peak current bypass protection control device applicable in MRAM shown in FIG. 7.

FIG. 9 is a schematic diagram showing control signals and MTJ element circuit signals which are used when performing read and write operations on the MRAM shown in FIG. 8.

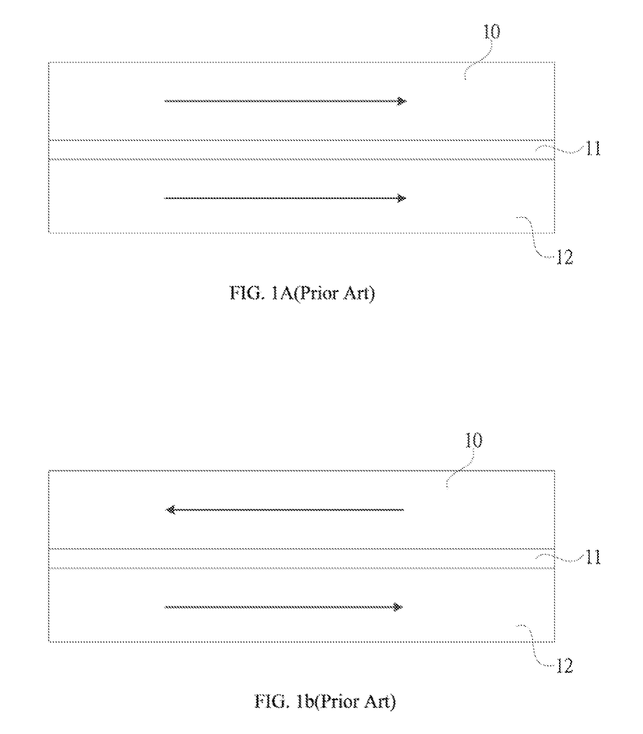

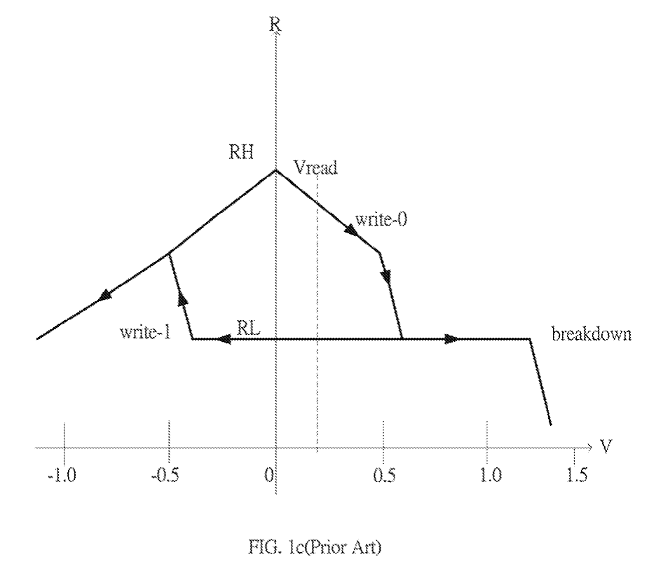

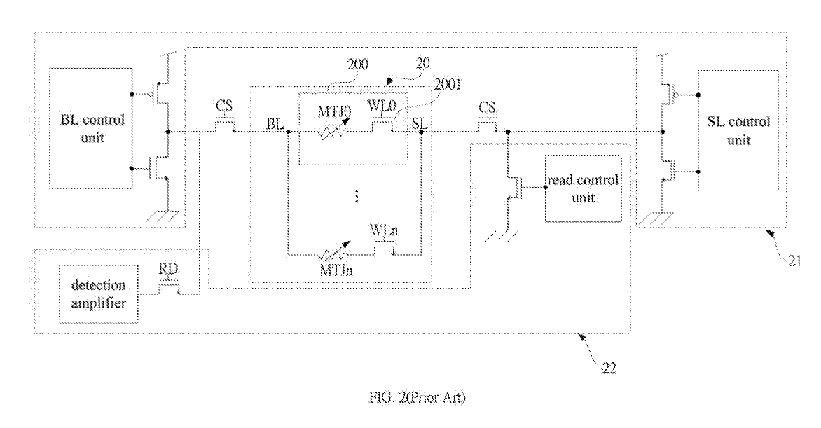

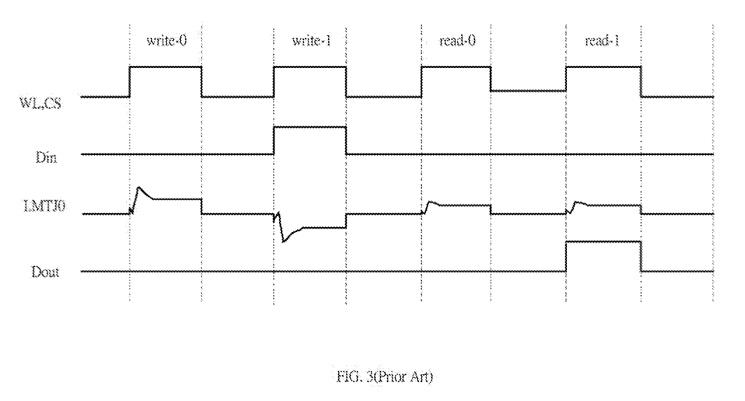

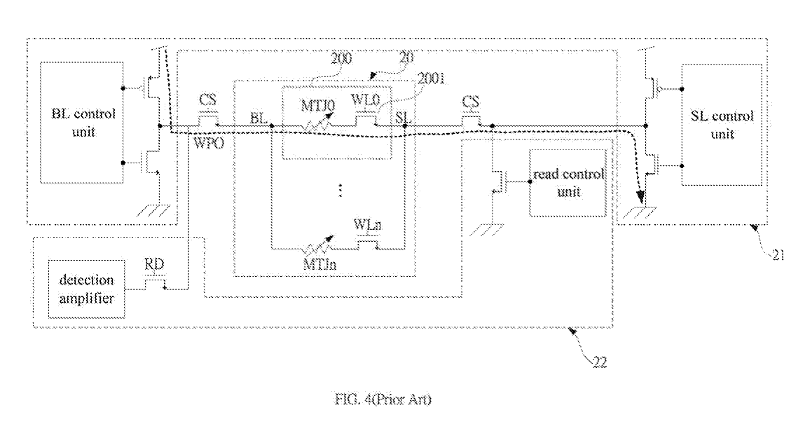

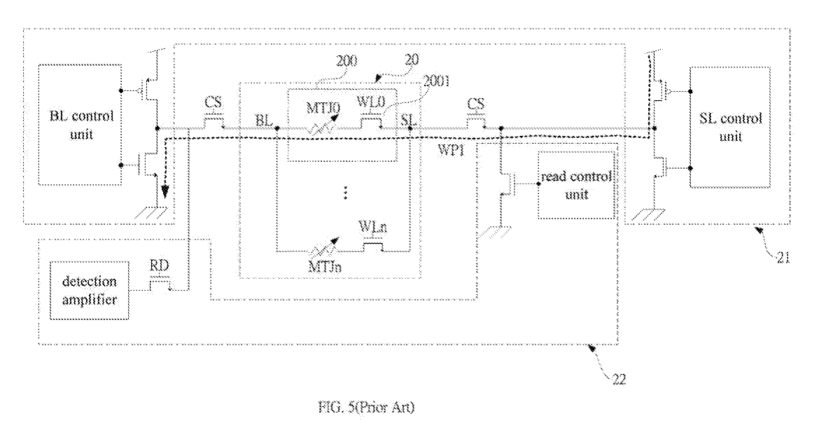

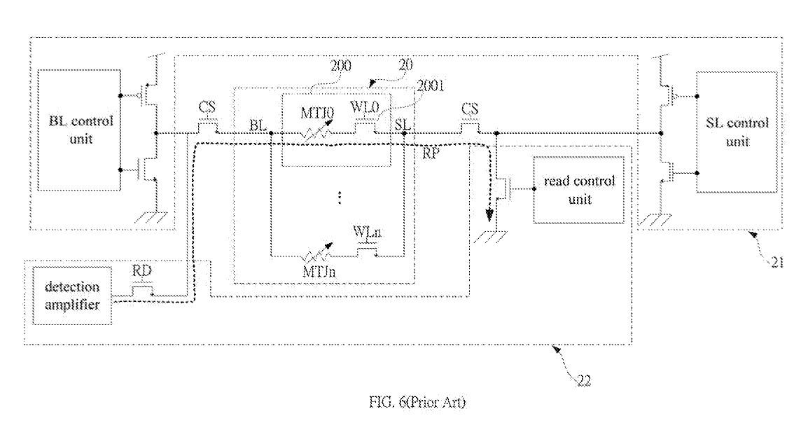

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

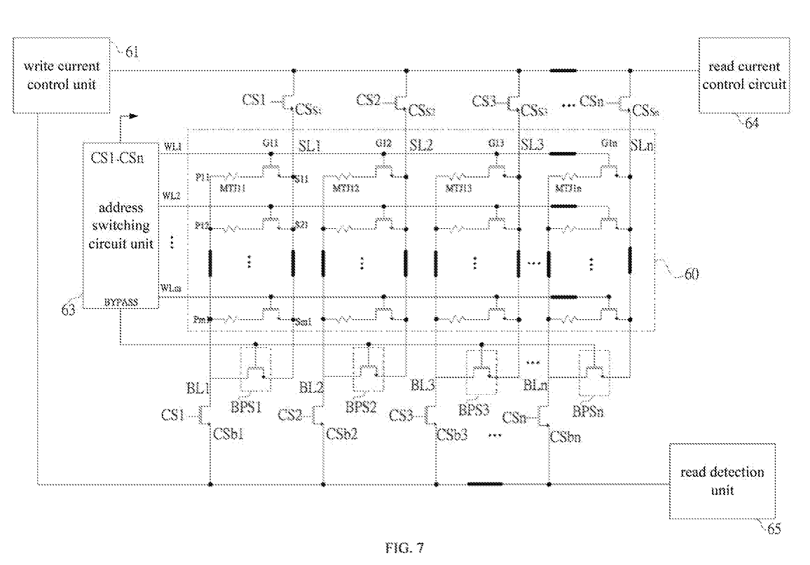

Referring to FIG. 7, it is a circuit architecture schematic diagram of a peak current bypass protection control device applicable in MRAM of the invention. As shown in FIG. 7, the MRAM circuit architecture includes a memory bit cell array 60 (specification: in rows×n columns). The memory bit cell array 60 includes in rows×n columns of magnetic memory bit cells, wherein each memory bit cell comprises a MTJ element and a drain of a transistor connected in series to the MTJ element. In the memory bit cell array 60, a terminal of each MTJ element, which is not connected to the transistor, serves as a first column control terminal (P11˜Pm1 as shown); a source of each transistor serves as a second column control terminal (S11˜Sm1 as shown); a gate of each transistor serves as a row control terminal (G11˜G1n). The MRAM circuit architecture further includes: a read/write control unit comprising a write current control unit 61, an address switching circuit unit 63, a read current control circuit 64 and a read detection unit 65, wherein the read and write current control units allow desirable magnetic memory bit cells that are to be read/written to be selected from the memory bit cell array 60 so as to read/write digital data from/to the selected magnetic memory bit cells; in row word lines (or row lines) WL1, WL2, . . . , WLm; n column bit lines (or column lines) BL1, BL2, . . . , BLn; n column source lines SL1, SL2, . . . , SLn; and bypass units BPS1˜BPSn. The address switching circuit unit 63 may confirm the magnetic memory bit cells, which are to be read, from the memory bit cell array 60. In this embodiment, it can be done by controlling the word lines WL1, WL2, . . . , WLm and column selection switches CSb1˜CSbn and CSs1˜CSsn to confirm the desired magnetic memory bit cells. More description thereof is as follows.

Each of the word lines WL1˜WLm has one end connected to the address switching circuit unit 63 and the other end connected to the row control terminals of all the magnetic memory bit cells in the corresponding row of the memory bit cell array 60 (that is, transistor gates G, and thus the row control terminals are also referred to as word line control terminals). For example, the word line WL1 is connected to the row control terminals G11˜G1n of all the magnetic memory bit cells in the first row of the memory bit cell array 60.

Each of the bit lines BL1˜BLn has one end connected to the write current control unit 61 and the other end connected to the first column control terminals of all the magnetic memory bit cells in the corresponding column of the memory bit cell array 60 (thus, the first column control terminals are also referred to as bit line control terminals). For example, the bit line BL1 is connected to the first column control terminals P11˜Pm1 of all the magnetic memory bit cells in the first column of the memory bit cell array 60. Each of the bit lines BL1˜BLn is connected in series with a corresponding column selection switch CSb1˜CSbn.

Each of the source lines SL1˜SLn has one end connected to the write current control unit 61 and the other end connected to the second column control terminals of the magnetic memory bit cells in the corresponding column of the memory bit cell array 60 (thus, the second column control terminals are also referred to as source line control terminals). For example, the source line SL1 is connected to the second column control terminals S11˜Sm1 of all the magnetic memory bit cells in the first column of the memory bit cell array 60. Each of the source lines SL1˜SLn is connected in series with a corresponding column selection switch CSs1˜CSsn.

When a write operation of digital data 0 or 1 is to be performed on a particular magnetic memory bit cell in the memory bit cell array, the write current control unit 61 and the address switching circuit unit 63 allow a desired magnetic memory bit cell to be selected from the memory bit cell array 60, such that a write operation current may flow from the bit line BL of the selected magnetic memory bit cell through the memory bit cell to the source line SL (current flow from BL to SL is defined as “positive”, and the digital data being written is for example 0). On the other hand, the write operation current may flow from the source line SL of the magnetic memory bit cell through the memory bit cell to the bit line BL (current flow from SL to BL is defined as “negative”, and the digital data being written is for example 1). When a read operation of digital data is to be performed on a particular magnetic memory bit cell in the memory bit cell array 60, the write current control unit 61, the address switching circuit unit 63 and the read current control circuit 64 allow a desired magnetic memory bit cell to be selected from the memory bit cell array, such that a read operation current may flow from the selected magnetic memory bit cell to the read detection unit 65. The read detection unit 65 detects and determines whether the digital data stored in the magnetic memory bit cell is 1 or 0 according to a reference signal, and outputs the detection result. As the read/write technology for MRAM is conventional and not a critical feature of the invention, the read/write control unit and the read/write operation are not to be further detailed here.

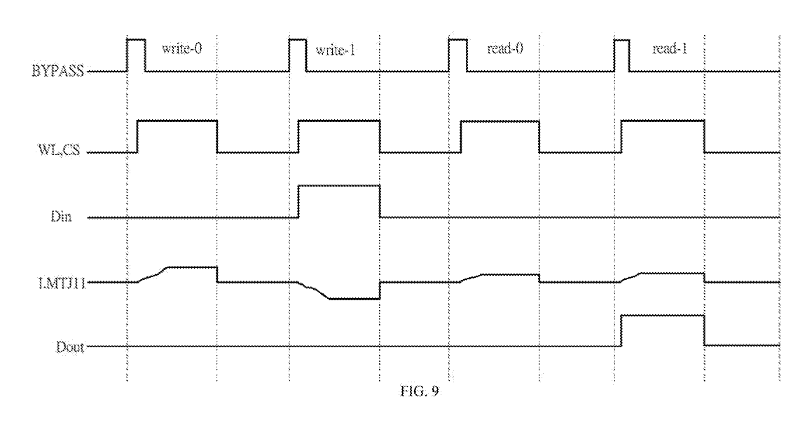

Further referring to FIG. 7, the bypass units BPS1˜BPSn are respectively connected to the first column control terminals (connected with the bit lines BL) and the second column control terminals (connected with the source lines SL) of n columns of the magnetic memory bit cells. In this embodiment, the bypass units BPS1˜BPSn are in the form of transistors, wherein gates of these bypass transistors are connected to the address switching circuit unit 63. In this case, when the address switching circuit unit 63 selects a desired magnetic memory bit cell that is to be read, a column selection control signal CS1˜CSn is outputted from the address switching circuit unit 63 in order to select a column selection switch CSb1˜CSbn and CSs1˜CSsn that is to be switched on, a row selection control signal is outputted via the word lines WL1, WL2, . . . , WLm, and a bypass signal BYPASS is also outputted. Thereby, when the address switching circuit unit 63 selects a particular magnetic memory bit cell in a particular column of the memory bit cell array, the bypass unit that is connected in parallel with the selected column of magnetic memory bit cells is to be turned on (that is, triggered). For example of the bypass unit BPS1, it is connected to the bit line BL1 and the source line SL1 and in parallel with in rows of magnetic memory bit cells in the first column of the memory bit cell array. When read/write operations are performed on the magnetic bit cells of the array, at the moment of applying read/write control signals WL/CS, Din, BYPASS impulse signals as shown in FIG. 9 to switch on selection switches (such as the above switches CSb1˜CSbn and CSs1˜CSsn, the transistors in the magnetic memory bit cells, etc.) in read/write paths, a peak current loaded on the read/write path can be guided out via the bypass unit BPS1 so as to suppress the peak current that flows through the read/write paths. This allows the current flowing through each of the MTJ elements to be more compliant with the working current for read/write operations (such as current I.MTJ11 flowing through the MTJ element MTJ11, as shown in FIG. 9), thereby improving the reliability of the magnetic memory bit cells and assuring correctness of digital data being read/written.

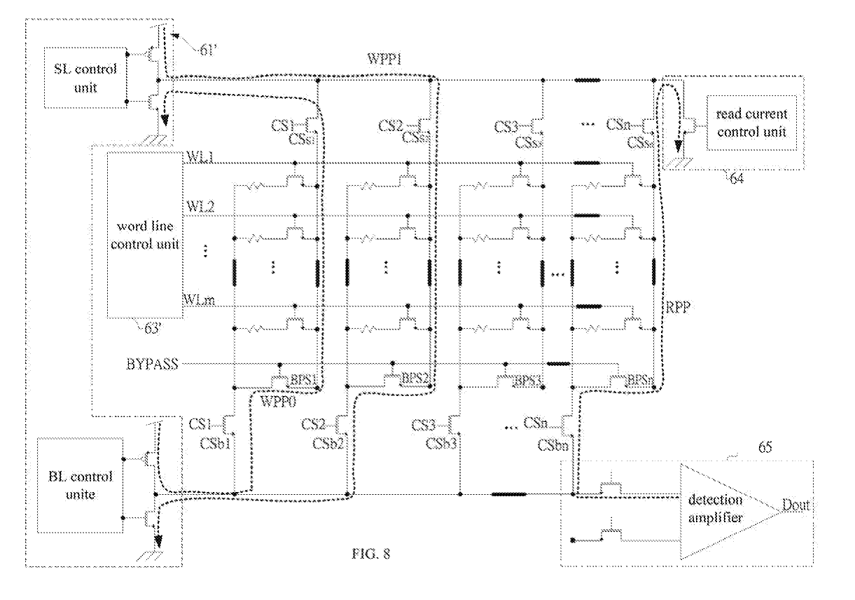

FIG. 8 shows another embodiment of the peak current bypass protection control device applicable in MRAM of the invention. In FIG. 8, the architecture of the above bypass units BPS1˜BPSn is illustrated. In this embodiment, the bypass units BPS1˜BPSn are transistors turned on at high potentials; while in other embodiments, the bypass units BPS1˜BPSn may also be transistors turned on at low potentials. FIG. 8 also shows the structure of the read/write control unit. For example in this embodiment, source line current signals and bit line current signals of the write current control unit 61′ are outputted as a result of the interaction of respective control units with transistors having opposite polarities. This allows the respective control units to turn on the transistors and thus allows a write current to flow through one of the memory bit cells of the memory bit cell array to perform the write operation. FIG. 8 further shows that the read current control circuit 64 is composed of a read control unit and a transistor, for controlling currents used for read operations. The read detection unit 65 is composed of a transistor and a comparator, for comparing read current signals and reference signals.

Therefore in the invention, one transistor switch is provided and connected in parallel to each column of magnetic memory bit cells of a memory bit cell array and serves as a bypass circuit. In a read/write operation, at the moment of switching on a selection switch (a switch element such as column selection switches CSb1˜CSbn and CSs1˜CSsn shown in FIGS. 7 and 8), a peak current is avoided from flowing through magnetic memory bit cells on a read/write path and is guided out. As shown in FIG. 8, at the time of switching on a selection switch when MRAM is writing signal “0”, a peak current generated at this moment can be guided through a guiding path WPP0 provided by the bypass unit (BPS1˜BPSn) in the invention to a ground terminal provided by a source line control circuit of the write current control unit 61. In the case of MRAM being writing signal “1” and thus switching on a selection switch, a peak current generated at this moment can be guided through a guiding path WPP1 provided by the bypass unit (BPS1˜BPSn) in the invention to a ground terminal provided by a bit line control circuit of the write current control unit 61. In the case of a read operation being performed and thus a selection switch being switched on, a peak current generated at this moment can be guided through a guiding path RPP provided by the bypass unit (BPS1˜BPSn) in the invention to a ground terminal of the read current control circuit 64. This thereby prevents instantaneous peak currents from flowing through the MTJ elements on the read/write paths, so as to keep currents on the MTJ elements within appropriate working ranges thereof and thus assure reliability of the MTJ elements.

It is to be noted that, FIGS. 7 and 8 are merely illustrative embodiments of the circuit architecture of the peak current bypass protection control device applicable in MRAM of the invention. This means the column/row arrangement of the source lines SL, bit lines BL and word lines WL is not limited to what is shown in the above embodiments. It should be understood that, the source lines SL and bit lines BL may be located in the rows while the word lines WL may be located in the columns. In such a case, the above first column control terminals can be referred to as bit line control terminals, the above row c control terminals can be referred to as word line control terminals, and the above second column control terminals can be referred to as source line control terminals. Therefore, different embodiments may have different column/row arrangements in the MRAM circuit architecture.

The examples above are only illustrative to explain principles and effects of the invention, but not to limit the invention. It will be apparent to those skilled in the art that modifications and variations can be made without departing from the scope of the invention. Therefore, the protection range of the rights of the invention should be as defined by the appended claims.

1. A peak current bypass protection control device applicable in MRAM, wherein the MRAM is controlled by a source line control circuit, an address switching circuit unit, a bit line control circuit and a read current control circuit to allow read/write operations to be performed thereon, and the MRAM has a memory bit cell array including a plurality of rows of magnetic memory bit cells and a plurality of columns of magnetic memory bit cells, wherein each of the magnetic memory bit cells comprises a MTJ element and a switch unit connected to a terminal of the MTJ element, wherein the switch unit comprises a transistor including a drain connected to the terminal of the MTJ element, wherein another terminal of the MTJ element serves as the bit line control terminal, a gate of the transistor serves as the word line control terminal, and a source of the transistor serves as the source line control terminal, and includes a bit line control terminal, a word line control terminal and a source line control terminal; the peak current bypass protection control device including:
a bit line connected to the bit line control circuit and provided for each of the columns of magnetic memory bit cells, wherein the bit line is connected to the bit line control terminal of each of the magnetic memory bit cells in a corresponding one of the columns;
a word line connected to the address switching circuit unit and provided for each of the rows of magnetic memory bit cells, wherein the word line is connected to the word line control terminal of each of the magnetic memory bit cells in a corresponding one of the rows; and
a bypass unit provided for each of the columns of magnetic memory bit cells, wherein the bypass unit is connected to the bit line control terminals and the source line control terminals of the magnetic memory bit cells in a corresponding one of the columns, wherein the bypass unit comprises a gate connected to the address switching circuit unit, and the bit line control terminals and the source line control terminals of the magnetic memory bit cells in each of the columns are respectively connected to a column selection switch, wherein the column selection switch is connected to the address switching circuit unit; and wherein the address switching circuit unit is for outputting a column selection control signal to the column selection switch, for outputting a row selection control signal to one of the rows of magnetic memory bit cells, and for outputting a bypass signal to the gate of the bypass transistor, wherein when the MRAM is writing signal “0” and switching on a selection switch connected to the address switching circuit unit, an instantaneous peak current being generated is guided through a guiding path provided by the bypass unit to a ground terminal provided by the source line control circuit, wherein when the MRAM is writing signal “1” and switching on a selection switch connected to the address switching circuit unit, an instantaneous peak current being generated is guided through a guiding path provided by the bypass unit to a ground terminal provide by the bit line control circuit, and wherein when the MRAM is performing a read operation and switching on a selection switch connected to the address switching circuit unit, an instantaneous peak current being generated is guided through a guiding path provided by the bypass unit to a ground terminal provide by the read current control circuit.

2. The peak current bypass protection control device applicable in MRAM according to claim 1, wherein the magnetic memory bit cell includes a MTJ element and a switch unit connected to a terminal of the MTJ element.

3. (canceled)

4. The peak current bypass protection control device applicable in MRAM according to claim 1, wherein the bypass unit is a switch unit.

5. The peak current bypass protection control device applicable in MRAM according to claim 4, wherein the switch unit is a bypass transistor turned on at a low potential or a high potential.

6. (canceled)

7. The peak current bypass protection control device applicable in MRAM according to claim 1, wherein the column selection switch is a selection transistor having a gate connected to the address switching circuit unit, for turning on one of the columns of magnetic memory bit cells according to the column selection control signal.

8-10. (canceled)
